(19) United States
(12) Patent Application Publication
(10) Pub. No.: US 2013/0313584 A1
(43) Pub. Date: Nov. 28, 2013

(54) LED illumination device having a first LED chip and a second LED chip, and a method for the production thereof

(71) Applicants: Martin Rudolf Behringer, Regensburg (DE); Elmar Baur, Regensburg (DE)

(72) Inventors: Martin Rudolf Behringer, Regensburg (DE); Elmar Baur, Regensburg (DE)

(73) Assignee: OSRAM OPTO SEMICONDUCTORS GmbH, Regensburg (DE)

(21) Appl. No.: 13/881,243

(22) PCT Filed: Jan. 25, 2012
(86) PCT No.: PCT/EP2012/051156

§ 371 Date: Jun. 11, 2013

(30) Foreign Application Priority Data
Feb. 9, 2011 (DE) 10 2011 010 752.5

(51) Int. Cl. H01L 33/00; H01L 27/15

(52) U.S. Cl. CPC H01L 33/005; H01L 27/15
USPC 257/89; 438/7

(57) ABSTRACT

An LED illumination device (10) having a first LED chip (1) and a second LED chip (2) is described, wherein the first LED chip (1) is suitable to emit radiation having a first emission characteristic (A1) and the second LED chip (2) is suitable to emit radiation having a second emission characteristic (A2). The first emission characteristic (A1) and the second emission characteristic (A2) have temperature-dependent changes (ΔA_{1T}, ΔA_{1T}), wherein the temperature-dependent change (ΔA_{1T}) in the first emission characteristic (A1) and the temperature-dependent change (ΔA_{2T}) in the second emission characteristic (A2) are, in operation, at least partially compensated for or are synchronised with respect to each other such that the chromaticity co-ordinate remains stable. Furthermore, a method for producing such an illumination device (10) is described.

LED illumination device having a first LED chip and a second LED chip, and a method for the production thereof

The present application relates to an LED illumination device having a first LED chip and a second LED chip which each emit radiation having an emission characteristic. The application further relates to a method for producing such an LED illumination device.

In order to produce devices which emit warm white light, LED chips which emit radiation having a different chromaticity co-ordinate are frequently combined. However, the individual LED chips behave differently at different temperatures. For example, the emitted output of the LED chips decreases differently and/or the wavelengths of the emitted radiation are shifted differently. As a result, the chromaticity co-ordinate of the mixed radiation emitted by the device changes. For example, the radiation emitted by the device which was originally warm white obtains a blue or red tint. In particular, the radiation emitted by the device is shifted towards blue when the ambient temperature and/or operating temperature rises, whereas the radiation is shifted towards red when the ambient temperature and/or operating temperature falls.

In order to prevent the change in output of individual LED chips or the wavelength shift, the temperature of the surroundings of the device or the chromaticity co-ordinate of the mixed radiation emitted by the device is frequently measured and the operating current of the individual LED chips is adjusted such that the chromaticity co-ordinate of the radiation emitted by the device remains substantially constant. For example, at high temperatures the operating current of a mint-coloured LED chip is reduced and the operating current of an amber-coloured LED chip is increased.

However, by means of this method of adapting the chromaticity co-ordinate, a complex current control or chromaticity co-ordinate measurement is required, whereby the costs of such a device increase disadvantageously.

An object of the application is to provide an improved LED illumination device in which differences in the emission characteristic, based on temperature fluctuations, are not perceptible by the human eye and which at the same time offers cost advantages. In particular, differences in the colour impression in such devices are reduced. Furthermore, an improved method of producing such an illumination device is provided.

This object is achieved inter alia by an LED illumination device having the features of Claim 1. Furthermore, this object is achieved by a method of producing such an illumination device having the features of Claim 9. Advantageous developments of the device and of the production method are described in the dependent claims.

In an embodiment, the LED illumination device comprises at least one first LED chip and one second LED chip, wherein the first LED chip is suitable to emit radiation having a first emission characteristic and the second LED chip is suitable to emit radiation having a second emission characteristic. The first emission characteristic and the second emission characteristic have temperature-dependent changes, wherein the temperature-dependent change in the first emission characteristic and the temperature-dependent change in the second emission characteristic are, in operation, at least partially compensated for or are synchronised with respect to each other such that the chromaticity co-ordinate is stable. “Stable” can mean that the chromaticity co-ordinate is shifted by at the most 0.02 or by at the most 0.01 units in the CIE chromaticity diagram.

The LED chips of the illumination device thus have different temperature dependencies which, when the device is in operation, are at least partially compensated for or are synchronised with respect to each other. As a result, a complex current control or chromaticity co-ordinate measurement can be omitted, whereby the costs of such a device can be considerably reduced advantageously.

The LED chips of the device are consequently combined with each other in an intelligent manner such that the different temperature behaviour, which affects the emission characteristic of the individual LED chips, does not, in total, have an effect on the mixed radiation emitted by the device. The different temperature behaviours of the LED chips are thus, in combination, not perceptible by the naked human eye.

The changes in the emission characteristics of the individual LED chips may be perceptible by the naked human eye. The mixed radiation emitted by the device is advantageously composed of a superimposition of the radiations emitted by the individual LED chips which means that the changes in the individual LED chips perceptible by the naked eye are, in total, at least partially cancelled out.

The first and second emission characteristic of the LED chips relates for example to properties relating to the brightness sensitivity curve of the eye, such as for example colour rendering index, luminous flux, colour temperature, chromaticity co-ordinate, luminous intensity or luminous density.

“Colour Rendering Index” (CRI) is understood to mean a photometric variable by means of which the quality of colour rendering of radiation-emitting components with identical correlated colour temperature can be described. The colour temperature is a measurement for the colour impression of a light source.

Luminous flux is a photometric variable which takes into account the wavelength-dependency of the sensitivity of the human eye, i.e. the V(λ) curve.

“Chromaticity co-ordinate” is understood to mean in particular the numerical values which describe the colour of the emitted radiation in the CIE colour space.

The changes in the emission characteristic can occur for example with increasing temperature owing to a reduction in the operating voltage of an LED chip at a constant current. This reduction in the operating voltage occurs owing to the band gap becoming smaller and owing to the decreasing contact resistance. This effect is also known to the person skilled in the art by the term “negative temperature coefficient”.

The operating voltage additionally depends upon the transverse conductivity of the used layers of the LED chips. This transverse conductivity is reduced as the temperature increases owing to the reduction in the average free path length of the charge carriers. This effect is also known to the person skilled in the art by the term “positive temperature coefficient”. The parameters of an LED chip determining the operating voltage thus have different temperature dependencies, wherein these temperature dependencies can change depending upon the configuration or design of the individual LED chips.

The individual LED chips of the LED device are configured such that the resulting temperature dependencies of the LED chips, in total, are compensated for or they take place in a synchronous manner with respect to each other which means that a constant chromaticity co-ordinate of the radiation emitted by the device can be ensured. If provision is made, for example, that the positive temperature coefficient of an LED chip is to prevail, then the absolute operating current has to be increased since thus the proportion of the series resistance which is provided by the transverse conductivity prevails over the band gap proportion.

In a development, the LED illumination device emits same-colour light in a temperature-independent manner during operation. The LED illumination device emits in particular mixed radiation of the radiation emitted by the first LED chip and the radiation emitted by the second LED chip. The emission characteristic of the mixed radiation has substantially no temperature dependencies since the temperature dependencies of the individual LED chips are, in operation, compensated for or synchronised with respect to each other. Thus, an LED illumination device can be obtained which emits mixed radiation having the same chromaticity co-ordinate with increasing and decreasing temperature. The blue tint which typically appears with increasing temperature or the red tint which appears with decreasing temperature can thus be reduced or obviated.

In a development, the LED illumination device emits mixed radiation having a constant chromaticity co-ordinate in a temperature-independent manner. The chromaticity co-ordinate emitted by the device is thus independent of a temperature change occurring during operation. “Having a constant chromaticity co-ordinate” means in particular that the mixed radiation has a constant chromaticity co-ordinate depending upon the eye sensitivity distribution of the human eye, said chromaticity co-ordinate thus may comprise small deviations but these are not perceptible by the human eye.

In a development, the change in the emission characteristics is a shift in the emitted wavelength and/or a change in output.

The first LED chip emits in particular radiation having a first wavelength. The second LED chip emits radiation having a second wavelength which is preferably different from the first wavelength. The first wavelength and the second wavelength are shifted during operation of the device in a temperature-dependent manner, wherein advantageously the shift in the first wavelength compensates for the shift in the second wavelength, or these shifts take place in a synchronous manner with respect to each other which means that the mixed radiation has a similar colour temperature independent of the temperature change. “Similar colour temperature” is understood to mean in particular that any occurring fluctuation in the colour temperature is not perceptible by the naked human eye.

In a development, the temperature-dependent change in the first emission characteristic is opposite to the temperature-dependent change in the second emission characteristic or takes place in a synchronous manner with respect to the temperature-dependent change in the second emission characteristic. By superimposing the radiations emitted by the LED chips, the temperature-dependent change in the first LED chip and the temperature-dependent change in the second LED chip are thus, for example, at least partially cancelled out with respect to each other.

The LED chips each preferably have a semiconductor layer sequence which contains an active layer. The semiconductor layer sequence contains at least one III/V-semiconductor material for radiation generation. The active layer preferably contains in each case a pn transition, a double heterostructure, a single quantum well (SQW) structure or multiple quantum well (MQW) structure for radiation generation. No significance in terms of the dimensionality of the quantisation should be derived from the designation “quantum well structure”. It includes inter alia quantum wells, quantum wires and quantum dots and any combination of these structures.

In a development, the first LED chip emits mint-coloured radiation. For example, the radiation emitted by the first LED chip is in a wavelength range between 480 and 520 nm.

In a development, the second LED chip emits amber-coloured radiation. For example, the radiation emitted by the second LED chip is in a wavelength range between 600 and 630 nm, preferably 615 nm.

In order to compensate for or synchronise the temperature-dependent behaviour of the first and second LED chip, the mint-coloured LED chip is configured such that as the temperature increases the voltage increases and the voltage of the amber-coloured LED chip decreases. For example, this configuration ensures that the light of the amber-coloured LED chip decreases to a lesser extent than the case without compensation. Ideally, the reduction in light of the amber-coloured LED chip corresponds as a result to the reduction in light of the mint-coloured LED chip. The temperature-dependency of the LED chips used is advantageously synchronised thereby.

Alternatively, the first LED chip emits blue radiation and the second LED chip emits red radiation. It should be noted in this case that the output of a blue LED chip decreases, with increasing temperature, to a lesser extent than the output of the red LED chip. The LED chips are thus configured such that the reduction in output of these LED chips takes place in a synchronous manner with respect to each other which means that the mixed radiation emitted by the device has a stable chromaticity co-ordinate.

In a development, the LED illumination device emits mixed radiation in the white spectral range, preferably in the warm white spectral range. The mixed radiation is thereby independent of a temperature change occurring during operation.

A method for producing at least one LED illumination device, which includes a first LED chip and a second LED chip, has the following method steps:
producing a plurality of first LED chips which are each suitable to emit radiation having a first emission characteristic,
producing a plurality of second LED chips which are each suitable to emit radiation having a second emission characteristic,
measuring temperature-dependent changes in the first emission characteristics of the first LED chips,
measuring temperature-dependent changes in the second emission characteristics of the second LED chips, and
combining the LED chips to form groups of in each case at least one first LED chip and one second LED chip such that the temperature-dependent change in the first emission characteristic and the temperature-dependent change in the second emission characteristic are at least partially compensated for or take place in a synchronous manner with respect to each other.

The features and advantages stated in conjunction with the LED illumination device are also applicable for the method, and vice-versa.

By way of the intelligent combination of LED chips with different temperature behaviours, changes in the emission characteristic can be cancelled out or synchronised such that the LED device, in total, emits mixed radiation which, in a temperature-dependent manner, has an emission characteristic which is constant for the human eye.

The LED chips of an illumination device are advantageously selected such that the temperature-induced reduction in output of the LED chips is similar or identical. This occurs for example by selecting the operating current in the case of an arrangement of the LED chips in a series connection, by selecting the operating voltage in the case of an arrangement of the LED chips in a parallel connection or by selecting suitable LED chips for the illumination device.

Alternatively, the compensation for, or synchronisation of, the temperature-dependent changes in the LED chips can be achieved by the design of the LED chips. For example, for this purpose the temperature-dependency of the current upon the voltage can be set or changed. This occurs for example via the weighting of the series resistance with respect to the voltage and with respect to the contact Schottky resistance.

In a development, the LED illumination device emits same-colour light in a temperature-independent manner during operation. Temperature-dependent shifts in the wavelength of the mixed radiation are preferably so small that the emitted mixed radiation is in the same chromaticity co-ordinate range in a temperature-independent manner.

In a development, the first LED chip is formed such that it compensates for, or takes place in a synchronous manner with respect to, the temperature-dependent change in the second emission characteristic of the second LED chip. The first LED chip is formed such that its resulting temperature-dependency changes such that it is opposite to, or takes place in a synchronous manner with respect to, the temperature-dependency of the second LED chip.

For example, the first LED chip is a mint-coloured LED chip, wherein a lateral distance between the n-contact and p-contact is increased for compensation purposes. As a result, in the temperature-dependency of the first LED chip the proportion of the series resistance with a positive temperature coefficient increases. If the second LED chip is an amber-coloured LED chip, then the temperature behaviour of the first LED chip progresses in a synchronous manner with respect to the temperature behaviour of the second LED chip by means of a mint-coloured LED chip configured in this manner.

Alternatively, for compensation or synchronisation purposes the first LED chip is formed such that the operating current of the first LED chip is increased. As a result, in the temperature-dependency of the first LED chip an increase in the proportion of the series resistance with a positive temperature coefficient is also achieved, whereby the temperature behaviour of the amber-coloured LED chip and of the mint-coloured LED chip can be synchronised with respect to each other.

In a development, in a common method a plurality of LED illumination devices are produced, wherein in each case an LED illumination device includes at least one first LED chip and one second LED chip which are each combined such that the temperature-dependent change in the first emission characteristic of the first LED chip and the temperature-dependent change in the second emission characteristic of the second LED chip are at least partially compensated for or take place in a synchronous manner with respect to each other. For this purpose, for example, the first LED chip can be configured such that the light emitted by the first LED chip decreases to a lesser extent in a temperature-dependent manner which means that ideally this light reduction corresponds to the light reduction of the second LED chip or takes place in an at least similar manner with respect thereto. Possible configurations of the LED chips have already been described above in this patent application and are thus not explained again at this juncture.

In a development, the LED illumination devices are each provided with a group of LED chips. The group of LED chips is composed at least of a first LED chip and a second LED chip.

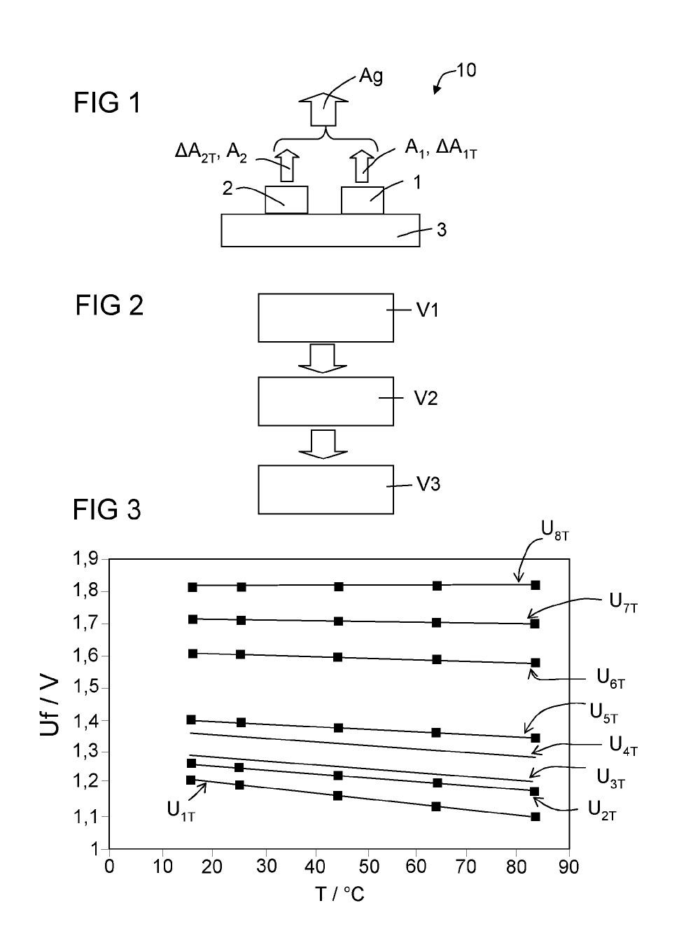

Further advantages and advantageous developments of the invention will be apparent from the exemplified embodiments described hereinafter in conjunction with FIGS. 1 to 3, in which:

FIG. 1 shows a schematic cross-section of an exemplified embodiment of an LED illumination device in accordance with the invention,

FIG. 2 shows a schematic flow diagram in conjunction with a production method in accordance with the invention, and

FIG. 3 shows a graph relating to the temperature-dependency of the voltage at different currents.

In the figures, identical parts or parts acting in an identical manner can be provided with the same reference numeral in each case. The illustrated parts and the size ratios with respect to each other are fundamentally to be considered as not being to scale. Rather, individual parts, such as for example layers, structures, components and regions may be illustrated excessively thick or with excessively large dimensions for ease of illustration and/or for better understanding.

FIG. 1 illustrates an LED illumination device 10 which comprises a carrier body 3, a first LED chip 1 disposed thereon and a second LED chip 2 disposed on the carrier body 3. The carrier body 3 is, for example, a printed circuit board, or PCB. Alternatively, a plurality of LED chips can be disposed on the carrier body 3 (not shown).

The LED chips 1, 2 each have an active layer which is suitable to generate electromagnetic radiation during operation. The LED chips 1, 2 are designed, for example, in a thin film construction. In particular, the LED chips 1, 2 preferably include epitaxially deposited layers which each form the LED chip. The layers of the LED chips 1, 2 are preferably based upon a III/V-compound semiconductor material.

The LED chips 1, 2 each comprise a radiation exit side which faces away from the carrier body 3. Preferably, the radiation emitted by the LED chips for the most part exits the radiation exit side in each case. For example, the LED chips 1, 2 are surface-emitting chips.

The first LED chip 1 is suitable to emit radiation having a first emission characteristic A1 during operation. The second LED chip 2 is suitable to emit radiation having a second emission characteristic A2 during operation. The emission characteristics A1, A2 include, for example, the wavelength, the chromaticity co-ordinate and/or the brightness of the radiation emitted by the LED chips 1, 2.

The first LED chip 1 preferably emits mint-coloured radiation in a wavelength range between 480 and 520 nm. The second LED chip 2 preferably emits amber-coloured radiation in a wavelength range between 600 nm and 630 nm, preferably 615 nm. A combination of a mint-coloured LED chip with an amber-coloured LED chip is suitable in particular for generating mixed radiation having a warm white chromaticity co-ordinate. In particular, the radiation emitted by the first LED chip 1 is superimposed during operation with the radiation emitted by the second LED chip 2 which means that the illumination device, in total, emits mixed radiation A_{g}.

The LED chips 1, 2 behave differently at different temperatures. For example, the emitted output decreases differently and/or the wavelengths of the emitted radiation are shifted differently. In particular, the first emission characteristic A1 and the second emission characteristic A2 have temperature-dependent changes ΔA_{1T}, ΔA_{2T}. Such temperature-dependent changes conventionally result in a change in the chromaticity co-ordinate of the mixed radiation Ag. For example, the radiation which was originally warm white has a blue tint when the temperature rises or a red tint when the temperature falls.

This effect is reduced or obviated by the present device 10 in that the temperature-dependent change ΔA_{1T} in the first emission characteristic A1 and the temperature-dependent change ΔA_{2T} in the second emission characteristic A2 are, in operation, at least partially compensated for or take place in a synchronous manner with respect to each other. Owing to this compensation for, or synchronisation of, the changes, an illumination device can be obtained which preferably emits same-colour light in a temperature-independent manner during operation. The LED illumination device 10 thus emits mixed radiation A_{g} with a constant chromaticity co-ordinate in a temperature-independent manner. “Constant chromaticity co-ordinate” means in particular that deviations in the chromaticity co-ordinate are not perceptible by the naked human eye. The illumination device, in particular the mixed radiation, is thus in particular independent of a temperature change occurring during operation.

Although the changes in the first emission characteristic A1 and in the second emission characteristic A2 are perceptible by the human eye, the superimposition of the radiations emitted by the LED chips, i.e., the mixed radiation A_{g}, has at the most a temperature-dependent change which is not perceptible by the naked human eye depending upon the eye sensitivity curve.

In order to effect such a compensation for, or synchronisation of, the changes in the emission characteristics, the temperature-dependent change ΔA_{1T} in the first emission characteristic A1 is opposite to the temperature-dependent change ΔA_{2T} in the second emission characteristic A2 or is directed in a synchronous manner with respect thereto. The first LED chip 1 is thus formed such that the voltage increases as the temperature increases for the case where, with increasing temperature, the emitted output decreases less strongly than the emitted output of the second LED chip 2 with the same or unchanged current. As a result, current and thus light of the first LED chip decrease with increasing temperature which means that the output reduction of the first LED chip 1 matches the output reduction of the second LED chip 2. It can hereby be achieved that the temperature-dependencies can be synchronised in relation to the output of the second LED chip and of the first LED chip and thus the chromaticity co-ordinate remains stable in a temperature-independent manner.

The change ΔA_{1T}, ΔA_{2T} in the emission characteristics A1, A2 appear for example by a shift in the emitted wavelength, i.e., the chromaticity co-ordinate, and/or by a change in output.

For example, the first LED chip emits radiation having a first wavelength and the second LED chip emits radiation having a second wavelength which differs from the first wavelength. During operation of the LED chips, the first wavelength and the second wavelength are shifted in a temperature-dependent manner, wherein the shift in the first wavelength is opposite to the shift in the second wavelength, or takes place in a synchronous manner with respect thereto, such that, in total, the shifts are at least partially compensated for or synchronised which means that the device emits mixed radiation having a constant chromaticity co-ordinate and being composed of a superimposition of the radiation of the first LED chip and of the emitted radiation of the second LED chip.

The LED chips of an illumination device are thus formed such that detected temperature-dependencies in the mixed radiation emitted by the device 10 are not visible. LED chips having different temperature-dependencies are thus combined such that a complex current control or chromaticity co-ordinate measurement during operation of the LED chips can be obviated, whereby the costs of such a white light device are advantageously reduced.

In order to compensate for or synchronise the changes in the emission characteristic, for example the first LED chip 1 can be formed such that a lateral distance between the n-contact and p-contact of the first LED chip 1 is increased. Owing to this increase, the proportion of the series resistance with positive temperature coefficients in the temperature-dependency of the first LED chip advantageously increases, whereby the temperature-dependency of the second LED chip can be counteracted or synchronised.

Alternatively or in addition, the first LED chip can be formed for compensation or synchronisation such that the operating current of the first LED chip 1 is increased. As a result, the effect of increasing the proportion of the series resistance with a positive temperature coefficients in the temperature-dependency of the LED chip can likewise be achieved. This can be produced, for example, in that the first LED chip 1 is connected in series with a plurality of second LED chips 2 which are connected in parallel with each other (not shown). The current, which flows completely through the first LED chip 1, is thus divided onto the second LED chip 2 which means that the current intensity through the second LED chip 2 is lower than the current intensity through the first LED chip 1. In general, a plurality of n first LED chips, which are connected in parallel with each other, can be connected in series with a plurality of m second LED chips which are also connected in parallel with each other, wherein n is smaller than m. n and m each refer to the number or quantity of respective LED chips 1, 2.

FIG. 2 shows a flow diagram for producing an LED illumination device, as illustrated for example in the exemplified embodiment of FIG. 1. In method step V1, a plurality of first LED chips and a plurality of second LED chips are produced and are each suitable to emit radiation having a first and second emission characteristic respectively. The first LED chips are preferably mint-coloured LED chips which thus emit radiation in the mint-coloured chromaticity co-ordinate range. The second LED chips are preferably amber-coloured LED chips, i.e., LED chips which emit radiation in the amber-coloured chromaticity co-ordinate range.

After the first and second LED chips have been produced, in method step V2 the temperature-dependent changes in the first or second emission characteristics are measured.

In method step V3, the LED chips are then combined to form groups of in each case at least one first LED chip and one second LED chip. The LED chips having different temperature behaviours are combined such that compensation for, or synchronisation of, the different temperature behaviours can be achieved. In particular, the groups of LED chips are combined such that the temperature-dependent change in the first emission characteristic of the first LED chip and the temperature-dependent change in the second emission characteristic of the second LED chip are at least partially compensated for, or take place in a synchronous manner with respect to each other. For example, the changes are completely compensated for.

Therefore, in the production method there is an intelligent combination of the individual LED chips based on measurements of the temperature-dependencies of the emission characteristics which means that an LED illumination device can be obtained which emits same-colour light in a temperature-independent manner during operation. Independently of a temperature change occurring during operation the mixed radiation emitted by the device thus has a virtually constant chromaticity co-ordinate.

The production method in accordance with the exemplified embodiment of FIG. 2 is also suitable to produce a plurality of LED illumination devices in a common method. In each case, an LED illumination device is preferably provided with a group of LED chips, wherein the LED chips of the individual illumination devices are combined such that the temperature-dependent changes in the emission characteristics are each compensated for or take place in a synchronous manner with respect to each other which means that each illumination device emits same-colour light in a temperature-independent manner during operation.

FIG. 3 illustrates a graph of the temperature-dependency of the voltage at different currents. In particular, eight measurement curves U_{1T} to U_{8T} are shown in the graph, wherein the current of U_{1T} to U_{8T} increases from 1 mA to 1000 mA. The measurement curve U_{1T} is based on currents of 1 mA, the measurement curve U_{2T} is based on currents of 5 mA, the measurement curve U_{3T} is based on currents of 10 mA, the measurement curve U_{4T} is based on currents of 50 mA, the measurement curve U_{5T} is based on currents of 100 mA, the measurement curve U_{6T} is based on currents of 500 mA, the measurement curve U_{7T} is based on currents of 750 mA and the measurement curve U_{8T} is based on currents of 1000 mA.

As shown in the graph, for low currents the voltage decreases with increasing temperature, see e.g., the measurement curves of U_{1T} to U_{6T}. At currents between 750 mA, in this case as U_{7T}, and 1000 mA, in this case as U_{8T}, the temperature-dependency disappears. At currents of over 1000 mA, the voltage increases (not shown).

A detection or determination of these temperature-dependencies depending upon the operating current can be used to intelligently combine the LED chips for an illumination device in accordance with the invention, as explained in conjunction with the exemplified embodiments of FIGS. 1 and 2.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

This patent application claims the priority of German patent application 10 2011 010 752.5, the disclosure content of which is hereby incorporated by reference.

1-15. (canceled)

16. LED illumination device comprising at least one first LED chip and at least one second LED chip, wherein
the first LED chip is suitable to emit radiation having a first emission characteristic,
the second LED chip is suitable to emit radiation having a second emission characteristic,
the first emission characteristic and the second emission characteristic have temperature-dependent changes, and
the temperature-dependent change of the first emission characteristic and the temperature-dependent change of the second emission characteristic are, in operation, at least partially compensated for or are synchronised with respect to each other such that the chromaticity co-ordinate of mixed radiation emitted by the LED illumination device is stable.

17. LED illumination device according to claim 16, wherein
the LED illumination device emits same-colour light in a temperature-independent manner during operation.

18. LED illumination device according to claim 16, wherein
the LED illumination device emits mixed radiation having a constant chromaticity co-ordinate in a temperature-independent manner.

19. LED illumination device according to claim 16, wherein
the change in the emission characteristics is a shift in the emitted wavelength and/or a change in output.

20. LED illumination device according to claim 16, wherein
the temperature-dependent change in the first emission characteristic is opposite to the temperature-dependent change in the second emission characteristic or takes place in a synchronous manner with respect thereto.

21. LED illumination device according to claim 16, wherein
the first LED chip emits mint-coloured radiation.

22. LED illumination device according to claim 16, wherein
the second LED chip emits amber-coloured radiation.

23. LED illumination device according to claim 16,
which emits mixed radiation in the white spectral range.

24. Method for producing at least one LED illumination device according to claim 16, which includes a first LED chip and a plurality of second LED chips, comprising the following method steps:
producing a plurality of first LED chips which are each suitable to emit radiation having a first emission characteristic,
producing a plurality of second LED chips which are each suitable to emit radiation having a second emission characteristic,
measuring temperature-dependent changes in the first emission characteristics of the first LED chips,
measuring temperature-dependent changes in the second emission characteristics of the second LED chips, and
combining the LED chips to form groups of in each case at least one first LED chip and one second LED chip such that the temperature-dependent change in the first emission characteristic of the first LED chip and the temperature-dependent change in the second emission characteristic of the second LED chip are at least partially compensated for or take place in a synchronous manner with respect to each other.

25. Method according to claim 24, wherein
the LED illumination device emits same-colour light in a temperature-independent manner during operation.

26. Method according to claim 24, wherein
the first LED chip is formed such that it compensates for or synchronises the temperature-dependent change of the second emission characteristic of the second LED chip.

27. Method according to claim 26, wherein
for compensation purposes a lateral distance between the n-contact and p-contact of the first LED chip is increased.

28. Method according to claim 26, wherein
for compensation purposes the operating current of the first LED chip is increased.

29. Method according to claim 24, wherein in a common method a plurality of LED illumination devices are produced.

30. Method according to claim 29, having the additional method step:
providing each LED illumination device with a group of LED chips.

31. LED illumination device comprising at least one first LED chip and a plurality of second LED chip, wherein
the first LED chip is suitable to emit radiation having a first emission characteristic,
the second LED chip is suitable to emit radiation having a second emission characteristic,
the first emission characteristic and the second emission characteristic have temperature-dependent changes,
the temperature-dependent change of the first emission characteristic and the temperature-dependent change of the second emission characteristic are, in operation, at least partially compensated for or are synchronised with respect to each other such that the chromaticity co-ordinate of mixed radiation emitted by the LED illumination device is stable,
the radiation emitted by the first LED chip is in a wavelength range between 480 nm and 520 nm, inclusive,
the radiation emitted by the second LED chip is in a wavelength range between 600 nm and 630 nm, inclusive, and
the at least one first LED chip is electrically connected in series with the plurality of second LED chips which are electrically connected in parallel with each other.

32. LED illumination device according to claim 31, wherein
in its intended use a current intensity through the second LED chips is lower than a current intensity through the at least one first LED chip.

33. LED illumination device according to claim 31,
comprising a plurality of the first LED chips,
wherein n first LED chips, which are connected in parallel with each other, are connected in series with m second LED chips which are also connected in parallel with each other, wherein n is smaller than m and wherein n and m refer to the number of the first and second LED chips, respectively.
